(19) United States
(12) Patent Application Publication
(10) Pub. No.: US 2014/0053894 A1
(43) Pub. Date: Feb. 27, 2014

(54) GRADED GeSn ON SILICON

(71) Applicants: Radek Roucka, Mountain View, CA (US); Michael Lebby, Apache Junction, AZ (US); Scott Semans, Sunnyvale, CA (US)

(72) Inventors: Radek Roucka, Mountain View, CA (US); Michael Lebby, Apache Junction, AZ (US); Scott Semans, Sunnyvale, CA (US)

(21) Appl. No.: 13/593,305

(22) Filed: Aug. 23, 2012

(51) Int. Cl. H01L 31/0336; H01L 31/18; H01L 29/267; H01L 21/20

(52) U.S. Cl. 136/255; 438/478; 438/87; 257/191; 257/E21.09; 257/E31.005; 257/E29.081

(57) ABSTRACT

A method of fabricating a solar cell on a silicon substrate includes providing a crystalline silicon substrate, selecting a grading profile, epitaxially growing a template on the silicon substrate including a single crystal GeSn layer using the grading profile to grade Sn through the layer. The single crystal GeSn layer has a thickness in a range of approximately 3 μm to approximately 5 μm. At least two layers of high band gap material are epitaxially and sequentially grown on the template to form at least three junctions. The grading profile starts with the Sn at or near zero with the Ge at zero, the percentage of Sn varies to a maximum mid-area, and reduces the percentage of Sn to zero adjacent an upper surface.

### FIELD OF THE INVENTION

This invention relates in general to the formation of GeSn on silicon wafers and more specifically to the grading of the GeSn.

### BACKGROUND OF THE INVENTION

In the solar cell industry, it is known that germanium (Ge) is a desirable semiconductor material that absorbs substantial amounts of solar energy. Commercially, 3 junctions using III-V materials are deployed on a germanium substrate to emulate or match the solar spectrum. In these devices the higher energy of the solar spectrum (e.g. blue light) is absorbed by the high band gap materials, such as InGaP and InGaAs. There are major problems with the use of germanium wafers. Germanium wafers are expensive and constitute approximately 50% of the total cost of the device. Also, germanium wafers are heavy and very brittle so that they are generally limited in size to less than 6″ in diameter. Further, because the wafers are brittle they must be relatively thick which due to the thermal conductivity issue creates a cooling problem.

Presently, it has been found that the addition of tin (Sn) to germanium extends the absorption spectrum of a solar cell into lower energy light. Some efforts have been made in the prior art to grow GeSn on silicon substrates but the thickness of the layers is limited because of cracking and stress fractures. As an example, a description of one such prior art method can be found in U.S. Pat. No. 7,589,003, entitled “GESN Alloys and Ordered Phases with Direct Tunable Bandgaps Grown Directly on Silicon”, issued Sep. 15, 2009.

It would be highly advantageous, therefore, to remedy the foregoing and other deficiencies inherent in the prior art.

Accordingly, it is an object of the present invention to provide new and improved methods for the growth of single crystal Ge on silicon substrates and more specifically to the growth of single crystal GeSn on silicon substrates.

It is another object of the present invention to provide new and improved methods of forming Ge and/or GeSn template on a silicon substrate.

It is another object of the present invention to provide new and improved methods of fabricating solar cells including a GeSn template on a silicon substrate with IV and III-V layers of material.

It is another object of the present invention to provide new and improved solar cells with increased efficiency.

It is another object of the present invention to provide new and improved solar cells that are less costly and easier to produce.

### SUMMARY OF THE INVENTION

Briefly, the desired objects and aspects of the instant invention are achieved in accordance with a preferred method of fabricating a solar cell on a silicon substrate. The method includes providing a crystalline silicon substrate, selecting a grading profile, and epitaxially growing a template on the silicon substrate including a single crystal GeSn layer using the grading profile to grade Sn through the layer. The single crystal GeSn layer has a thickness in a range of approximately 3 μm to approximately 5 μm. The grading profile starts with the Sn at or near zero with the Ge at zero, the percentage of Sn varies to a maximum mid-area, and reduces the percentage of Sn to zero adjacent an upper surface. At least two layers of high band gap material are epitaxially and sequentially grown on the template to form at least three junctions.

The desired objects and aspects of the instant invention are also realized in accordance with a specific method of fabricating a solar cell on a silicon substrate. The method includes providing a crystalline silicon substrate, selecting a grading profile, and epitaxially growing a template on the silicon substrate including a single crystal GeSn layer using the grading profile to grade Sn through the layer. The single crystal GeSn layer has a thickness in a range of approximately 3 μm to approximately 5 μm. At least two layers of high band gap material are epitaxially and sequentially grown on the template to form at least three junctions.

The desired objects and aspects of the instant invention are also realized in accordance with a specific embodiment including a GeSn template on a silicon substrate including a crystalline silicon substrate and an epitaxially grown single crystal GeSn layer on the silicon substrate. The Sn is graded through the layer and the single crystal GeSn layer has a thickness in a range of approximately 3 μm to approximately 5 μm.

The desired objects and aspects of the instant invention are also realized in accordance with a specific embodiment including a solar cell on a silicon substrate. The solar cell includes a crystalline silicon substrate, an epitaxially grown template on the silicon substrate including an epitaxially grown single crystal GeSn layer on the silicon substrate. The Sn is graded through the layer and the single crystal GeSn layer has a thickness in a range of approximately 3 μm to approximately 5 μm. At least two layers of high band gap material are epitaxially and sequentially grown on the template forming at least three junctions.

### BRIEF DESCRIPTION OF THE DRAWINGS

The foregoing and further and more specific objects and advantages of the instant invention will become readily apparent to those skilled in the art from the following detailed description of a preferred embodiment thereof taken in conjunction with the drawings, in which:

FIG. 1 illustrates a simplified layer diagram of a prior art solar cell on a germanium substrate;

FIG. 2 is a graph illustrating the solar absorption of germanium relative to the thickness of the germanium;

FIG. 3 is a representation of the solar spectrum illustrating the absorption areas of germanium and GeSn;

FIG. 4 is a simplified layer diagram of a germanium template on a silicon substrate in accordance with the present invention;

FIGS. 5-9 are graphs illustrating some specific grading profiles for the deposition of GeSn and a germanium template in accordance with the present invention;

FIG. 10 illustrates in simplified layer diagrams a prior art solar cell with relation to three solar cells fabricated in accordance with the present invention;

FIG. 11 illustrates the relative efficiency of three solar cells in accordance with the present invention compared to a prior art solar cell;

FIG. 12 illustrates the specific construction of the FIG. 11(b) solar cell; and

FIG. 13 illustrates the specific construction of the FIG. 11(c) solar cell.

### DETAILED DESCRIPTION OF THE DRAWINGS

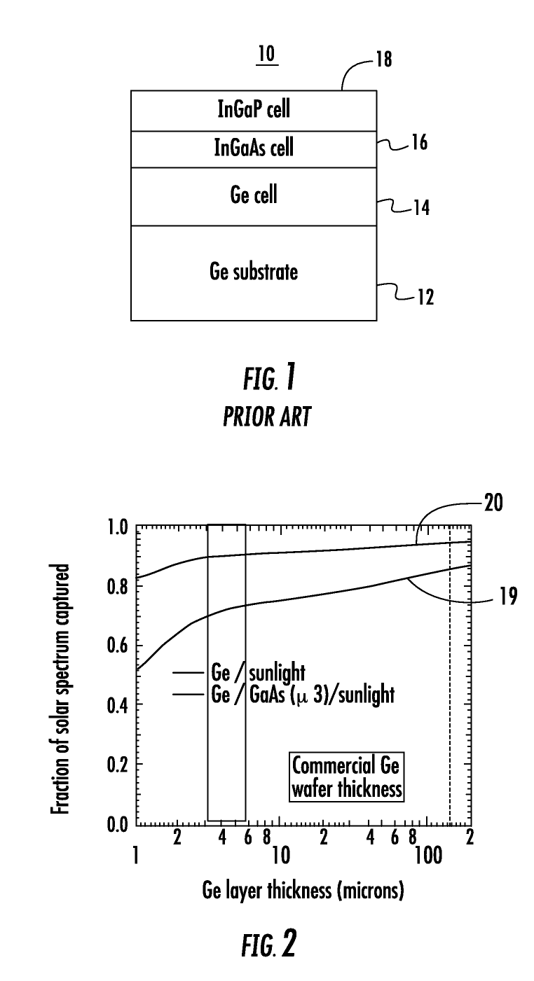

Turning to FIG. 1, a simplified layer diagram is illustrated of a prior art solar cell 10 on a germanium substrate 12. A Ge solar junction 14 is formed on a p-type Ge substrate 12 via diffusion of n-type dopant (typically As) during fabrication process of overlying layers (16 and 18). A layer 16 of InGaAs is epitaxially deposited on germanium layer 14 and a layer 18 of InGaP is epitaxially deposited on layer 16 to complete cell 10. Layers 16 and 18 are higher band gap materials that are included to absorb the higher energy light, such as blue light.

As explained above, germanium wafers are expensive and constitute approximately 50% of the total cost of solar cell 10. Also, germanium wafers are heavy and very brittle so that they are generally limited in size to less than 6″ in diameter so that fewer cells can be formed from each wafer (if the wafer is cut into rectangular cells) or a smaller cell (i.e. <6″) is produced. Thus, because of the smaller cell the cost of labor is increased. Further, because the wafers are brittle they must be relatively thick which due to the thermal conductivity issue creates a cooling problem.

Turning to FIG. 2, the graph illustrates the solar absorption of germanium relative to the thickness of the germanium. The lower curve, designated 19, illustrates the absorption of a germanium layer and the upper curve, designated 20, illustrates the absorption of a germanium layer with additional higher energy layers added. As illustrated in the graph, the germanium in either device provides substantially the maximum absorption between the thickness of 3 and 5 microns. Thus, when a germanium containing layer is included in a solar cell it is desirable to grow the layer to a thickness in the range of 3-5 microns for the maximum absorption and minimum effort and use of material. Here it should be noted that in the prior art devices and methods, layers of germanium and/or GeSn of this thickness have been difficult to achieve.

Referring additionally to FIG. 3, a representation of the solar spectrum is illustrated including the absorption areas of germanium, designated 22, and GeSn, designated 24. From this representation it can be seen that a shift of the lower absorption edge is obtained by including tin (Sn) In the solar cell material. It has been found that including approximately 2% tin with the germanium extends the detection range beyond the range of germanium by itself into the IR spectrum.

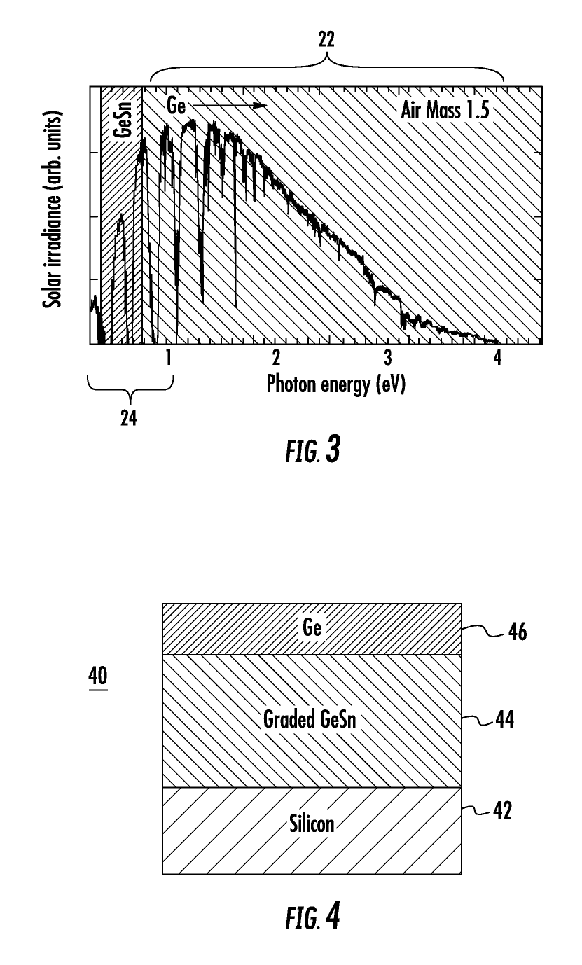

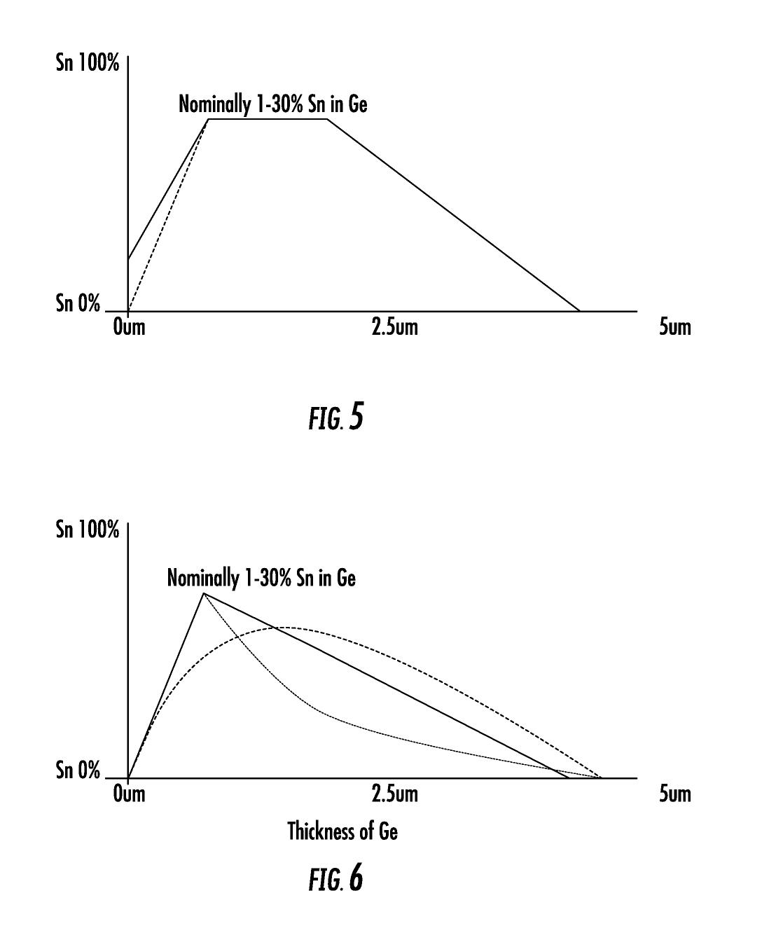

Referring specifically to FIG. 4, a simplified layer diagram is illustrated of a germanium template 40 on a silicon substrate 42 in accordance with the present invention. In this specific embodiment, template 40 includes a graded GeSn portion or layer 44 and a Ge portion or layer 46. It will be understood that portions 44 and 46 are generally formed from a single epitaxial growth process with the tin being graded in some selected profile. Further, while specific layers of GeSn and Ge are illustrated it will be understood that in accordance with the specific profile selected template 40 may be considered a GeSn template or a Ge template, as will be understood from the further examples set forth below. Here it will be understood that because silicon wafers can be made in much larger sizes (e.g. 6″, 8″, 12″, etc.) 2.5× more cells can be cut from a 6″ wafer and even more can be cut from larger wafers. In at least some instances the template may be grown on a Ge buffered Si (100) substrate or on a Si (111) substrate. The Si (100) and (111) substrates also include various miscuts with nominal value between 0 and 10° in any direction.

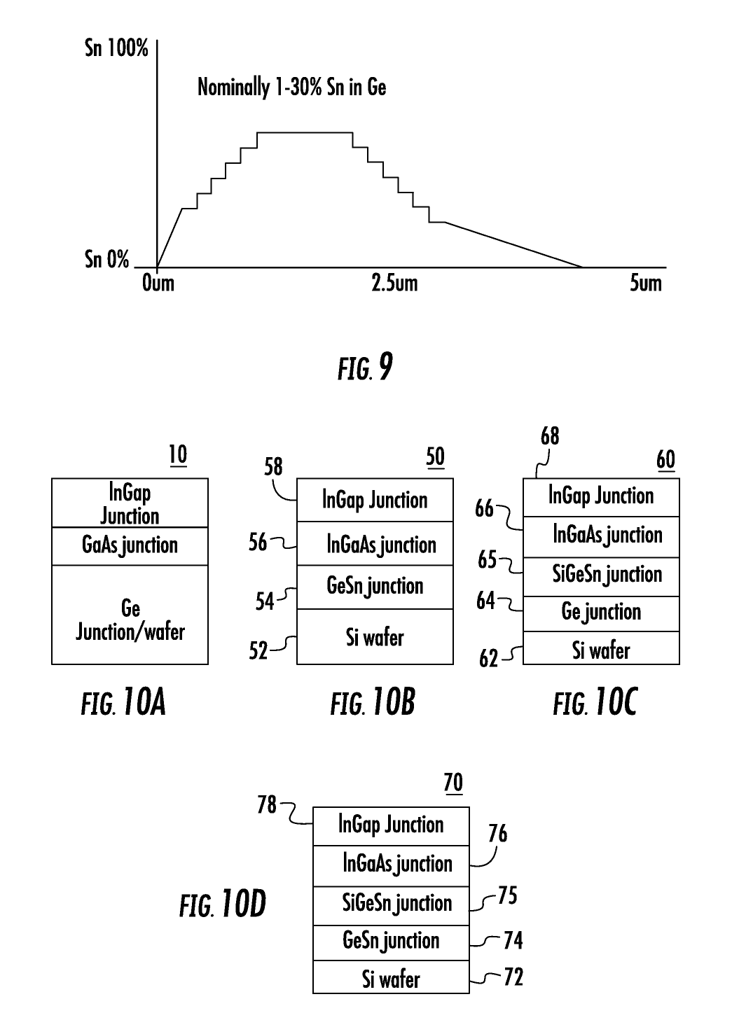

A wide variety of profiles may be used to deposit the desired amount of GeSn and to achieve the thickness required. It should be understood that by grading the tin with the germanium, templates in a range of 3 μm to 5 μm can be achieved. Grading consists of increasing the tin content from an initial point at or near zero to maximum in a mid-area and reducing the content to zero at or before the final area is reached. Referring additionally to FIGS. 5-9, examples of five different profiles that can be used to achieve the desired results are illustrated. Nominal value preferably is between 0.1 to 30% Sn. It is a target value, which is to be achieved in such a layer. The profile is used to reach such a nominal Sn content i.e. the Sn content is graded from 0 to the nominal value (0.3%) either continuously or in a stepped manner. From the different profiles it can be seen that the tin can be started at zero with the germanium or at some value, such as 0.3%. Further, the percentage of tin varies throughout the deposition generally tapering off from a maximum mid-area as the growth progresses. Each of these specific profiles has resulted in a desired template thickness of between approximately 3 μm and approximately 5 μm and the desired mix of germanium and tin. Further, because of the grading the desired thickness in the resulting layer can be achieved with higher crystalline quality and substantial elimination of cracking.

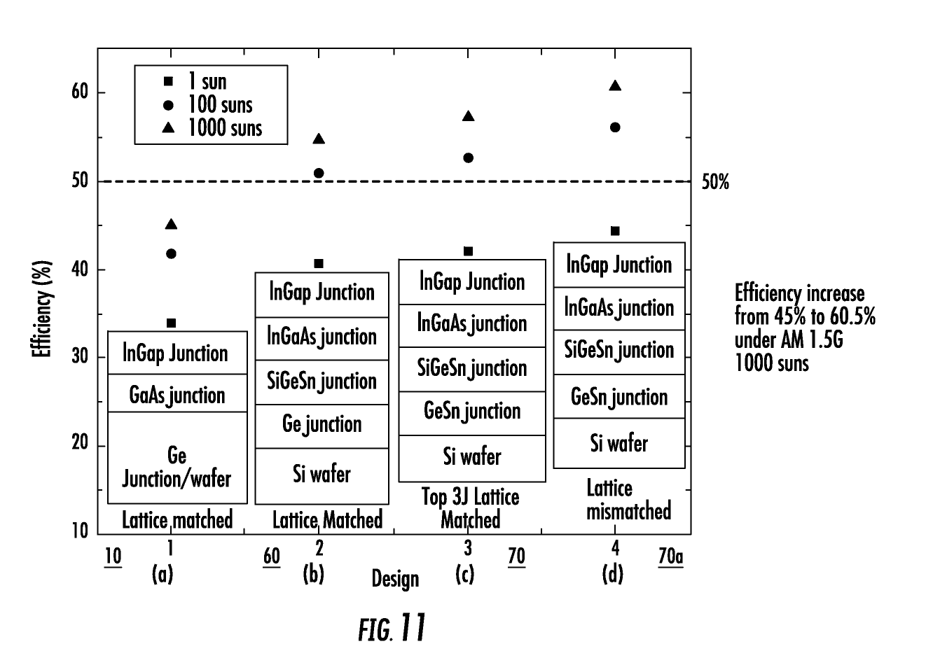

Turning now to FIG. 10, simplified layer diagrams of a prior art solar cell (a) with relation to three solar cells (b), (c) and (d) fabricated in accordance with the present invention are illustrated. An energy reference is illustrated at the left to show the approximate energy levels of the various layers in the four devices and the four devices are illustrated together to for ease in a comparison. The prior art device illustrated in (a) is the same device illustrated and described in conjunction with FIG. 1 and includes 3 junctions, InGaP/GaAs/Ge lattice matched to the germanium. In this instance with the higher energy layers lattice matched to germanium the energy levels of the layers are approximately 1.86/1.42/0.67 eV. “Metamorphic” is lattice mismatched and in some instances a metamorphic design allows better spectrum matching.

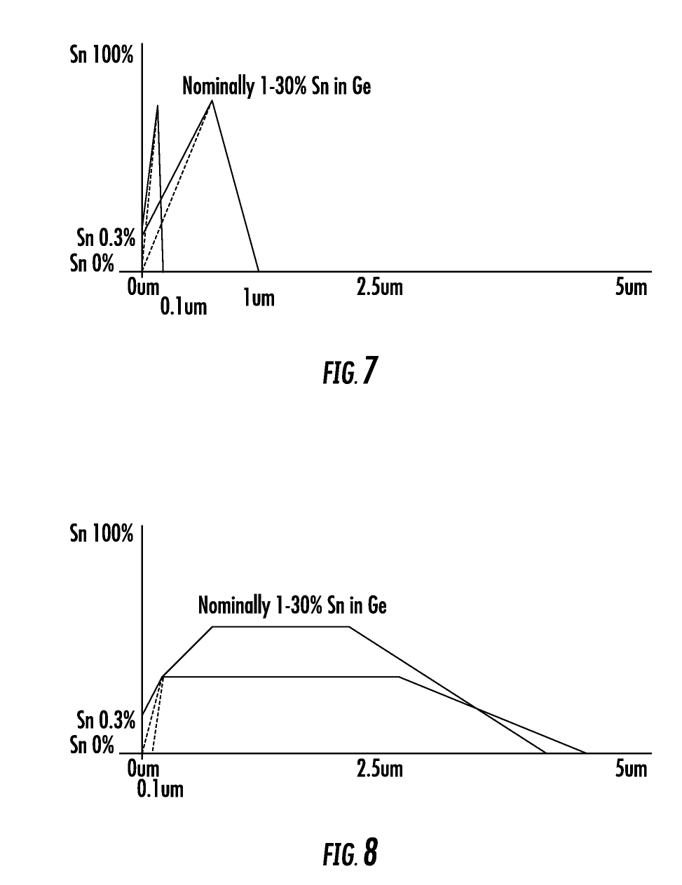

Referring specifically to FIG. 10(b), a solar cell designated 50 is illustrated. Solar cell 50 includes a silicon wafer 52 with a GeSn template 54 epitaxially grown thereon. In this specific embodiment template 54 is illustrated as GeSn and may be formed, for example, using a profile which includes tin substantially to the upper surface, such as the profile illustrated in FIG. 6. A layer 56 of InGaAs is epitaxially grown on template 54 and a layer 58 of InGaP is grown on layer 56 to form a three junction solar cell. Each of the two layers of high band gap material includes material with a band gap in a range of 0.8 eV to 3 eV. Preferably the entire cell is grown in one continuous operation without breaking the vacuum on the epitaxial chamber (i.e. in situ).

Solar cell 50 is lattice matched to silicon substrate 52 with GeSn template 54 only having a thickness in the range of approximately 3 μm to approximately 5 μm and the desired mix of germanium and tin, which allows the required growth thickness and provides improved crystal quality. Therefore, solar cell 50 can be manufactured much more inexpensively than solar cell 10 and can more efficiently absorb solar emissions. Further, this design allows even better spectrum matching because of the GeSn included in template 54.

Referring specifically to FIG. 10(c), a solar cell designated 60 is illustrated. Solar cell 60 includes a silicon wafer 62 with a Ge template 64 epitaxially grown thereon. In this specific embodiment template 64 is illustrated as Ge and is primarily included for the epitaxial growth of additional layers of material. A layer 65 of SiGeSn is epitaxially grown on Ge template 64 followed by the epitaxial growth of a layer 66 of InGaAs and a layer 68 of InGaP to form a four junction solar cell. Generally, each of the four layers of high band gap material (or at least two of the layers) includes material with a band gap in a range of 0.8 eV to 3 eV. Preferably the entire cell is grown in one continuous operation without breaking the vacuum on the epitaxial chamber (i.e. in situ).

Solar cell 60 is lattice matched to silicon substrate 62 with Ge template 64 which is relatively thin since it is primarily used to lattice match the upper layers to the silicon substrate. In this four junction example the energy levels of the layers are 1.86/1.40/˜1.0/0.67 eV. The new SiGeSn layer 65 has an energy level of approximately 1.0 eV which absorbs a major portion of the solar energy previously missed or at the lower edge of absorption and substantially improves performance of the solar cell. Because of the small Ge template lattice matching the cell to the silicon substrate, solar cell 60 can be manufactured much more inexpensively than solar cell 10 and because of the new SiGeSn layer can more efficiently absorb solar emissions. Further, the metamorphic design allows and the new SiGeSn layer even better spectrum matching can be achieved.

Referring specifically to FIG. 10(d), a solar cell designated 70 is illustrated. Solar cell 70 includes a silicon wafer 72 with a GeSn template 74 epitaxially grown thereon. In this specific embodiment template 74 is illustrated as GeSn and may be formed, for example, using a profile which includes tin substantially to the upper surface, such as the profile illustrated in FIG. 6 or 8. A layer 75 of SiGeSn is epitaxially grown on GeSn template 74 followed by the epitaxial growth of a layer 76 of InGaAs and a layer 78 of InGaP to form a four junction solar cell. Generally, each of the four layers of high band gap material (or at least two of the layers) includes material with a band gap in a range of 0.8 eV to 3 eV. Preferably the entire cell is grown in one continuous operation without breaking the vacuum on the epitaxial chamber (i.e. in situ).

Solar cell 70 is lattice matched to silicon substrate 72 with GeSn template 74 having a thickness in the range of approximately 3 μm to approximately 5 μm and the desired mix of germanium and tin (i.e. single crystal Ge₁₋ₓSnₓ, with x in a range between 0 to 0.3), which allows the required growth thickness and provides improved crystal quality as well as enhanced solar absorption. In this four junction example the energy levels of the layers are 1.86/1.40/˜1.0/0.65 eV. The new SiGeSn layer 75 has an energy level of approximately 1.0 eV which, along with the GeSn template 74, absorbs a major portion of the solar energy previously missed or at the lower edge of absorption and substantially improves performance of the solar cell. Because of the improved GeSn template lattice matching the cell to the silicon substrate, solar cell 70 can be manufactured much more inexpensively than solar cell 10 and because of the new SiGeSn layer along with the GeSn template 74 can more efficiently absorb solar emissions. Further, because the GeSn template has substantially eliminated fractures and forms a higher crystalline quality, the crystalline quality of the entire cell is improved and absorption is improved.

Referring additionally to FIG. 11, the relative efficiency of three solar cells in accordance with the present invention compared to a prior art solar cell is illustrated. The prior art device illustrated in (a) is the same device illustrated and described in conjunction with FIG. 1 and includes 3 junctions, InGaP/GaAs/Ge lattice matched to the germanium substrate. In this instance with the higher energy layers lattice matched to germanium the energy levels of the layers are approximately 1.86/1.42/0.67 eV. As indicated the efficiency of cell 10 is approximately 45% under AM 1.5G 1000 suns. All of the efficiencies in this figure are shown with 1 sun, 100 suns, and 1000 suns (taking the amount of solar collection or focused enhancement into consideration).

The solar cell illustrated in FIG. 11(b), is the same device designated 60, illustrated and described in conjunction with FIG. 10(c) and includes 4 junctions, InGaP/InGaAs/SiGeSn/Ge lattice matched to the silicon substrate. In this instance with the higher energy layers lattice matched to germanium through the new SiGeSn layer the energy levels of the layers are 1.86/1.40/˜1.0/0.67 eV. As indicated the efficiency of cell 60 is approximately 55% under AM 1.5G 1000 suns.

The solar cell illustrated in FIG. 11(c), is the same device designated 70, illustrated and described in conjunction with FIG. 10(d) and includes 4 junctions, InGaP/InGaAs/SiGeSn/GeSn lattice matched to the silicon substrate. In this instance with the higher energy layers lattice matched to germanium through the GeSn template the energy levels of the layers are 1.86/1.40/˜1.0/0.65 eV. As indicated the efficiency of cell 70 is approximately 57% under AM 1.5G 1000 suns.

The solar cell illustrated in FIG. 11(d), is essentially the same device designated 70a as illustrated and described in conjunction with FIG. 10(d). Cell 70a includes 4 junctions, InGaP/InGaAs/SiGeSn/GeSn, but the junctions are lattice mismatched slightly with better spectrum matching and with optimized band gap energies. It should be noted that while there is lattice mismatch between layers there is still sufficient match to allow single crystal growth of all the layers. In this instance with the layers lattice mismatched with better spectrum matching the energy levels of the layers are 2.13/1.55/1.13/0.53 eV. As indicated the efficiency of cell 70a is approximately 60.5% under AM 1.5G 1000 suns.

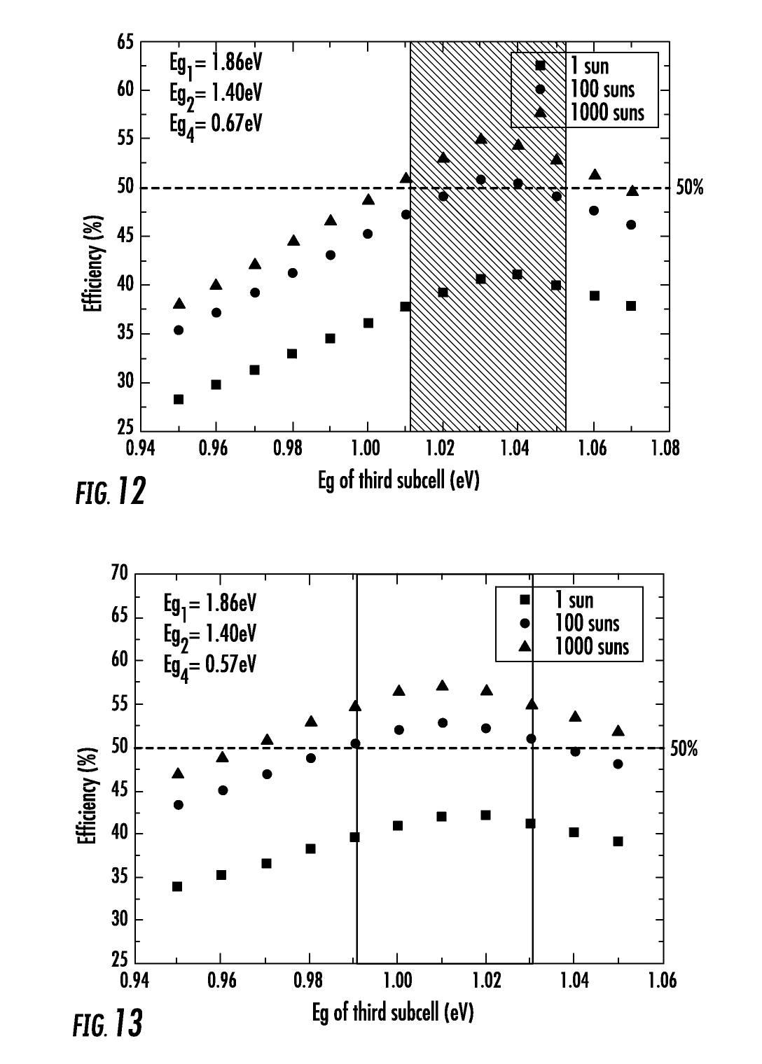

Referring additionally to FIGS. 12 and 13, the effect that the new layer SiGeSn has on the cell efficiency is illustrated in more detail. Referring specifically to FIG. 12 with the SiGeSn layer lattice matched to the Ge template (see for example cell 60) the energy levels of the four layers are 1.86/1.40/˜1.03/0.67 eV. The energy level of the SiGeSn layer is 1.03 with the efficiency reaching over 50%. Referring specifically to FIG. 13 with the SiGeSn layer lattice matched to the GeSn template (see for example cell 70) the energy levels of the four layers are 1.86/1.40/˜1.01/0.57 eV. The energy level of the SiGeSn layer is 1.01 with the efficiency reaching over 55%.

Thus it has been demonstrated that through the grading of tin during the growth of a GeSn template on a silicon substrate, a template thickness in the range of approximately 3 μm to approximately 5 μm is achieved. Also, the novel grading not only allows the required growth thickness but provides improved crystal quality. Further, by incorporating a new layer of SiGeSn with the new template a substantially improved four junction solar cell is formed with substantially improved efficiency. The four junction cell on a silicon substrate can either be crystal lattice matched or mismatched with better spectrum matching.

Thus, new and improved methods for the growth of single crystal GeSn on silicon substrates have been disclosed. Also, new and improved methods of fabricating solar cells including a new layer of SiGeSn on either a Ge template or a GeSn template on a silicon substrate with IV and III-V layers of material have been disclosed. Further, new and improved solar cells with increased efficiency and that are less costly and easier to produce are disclosed.

Various changes and modifications to the embodiments herein chosen for purposes of illustration will readily occur to those skilled in the art. To the extent that such modifications and variations do not depart from the spirit of the invention, they are intended to be included within the scope thereof which is assessed only by a fair interpretation of the following claims.

Having fully described the invention in such clear and concise terms as to enable those skilled in the art to understand and practice the same, the invention claimed is:

1. A method of forming a GeSn template on a silicon substrate comprising the steps of:
providing a crystalline silicon substrate;
selecting a grading profile; and
epitaxially growing a single crystal GeSn layer on the silicon substrate using the grading profile to grade Sn through the layer, the single crystal GeSn layer having a thickness in a range of approximately 3 μm to approximately 5 μm.

2. A method as claimed in claim 1 wherein the grading profile includes starting the Sn at or near zero with the Ge at zero, varying the percentage of Sn to a maximum mid-area, and reducing the percentage of Sn to zero as the growth progresses.

3. A method as claimed in claim 1 wherein the grading is terminated and a step of growing a layer of Ge completes the template.

4. A method of fabricating a solar cell on a silicon substrate comprising the steps of:
providing a crystalline silicon substrate;
selecting a grading profile;
epitaxially growing a template on the silicon substrate including a single crystal GeSn layer using the grading profile to grade Sn through the layer, the single crystal GeSn layer having a thickness in a range of approximately 3 μm to approximately 5 μm; and
epitaxially and sequentially growing at least two layers of high band gap material on the template to form at least three junctions.

5. A method as claimed in claim 4 wherein the step of epitaxially growing a template on the silicon substrate includes growing a single crystal Ge₁₋ₓSnₓ, with x in a range between 0 to 0.3.

6. A method as claimed in claim 4 wherein each of the at least two layers of high band gap material includes material with a band gap in a range of 0.8 eV to 3 eV.

7. A method as claimed in claim 6 wherein a layer of the at least two layers of high band gap material adjacent the template includes InGaAs.

8. A method as claimed in claim 7 wherein another layer of the at least two layers of high band gap material includes a layer of InGaP epitaxially grown on the layer including InGaAs.

9. A method as claimed in claim 6 wherein a layer of the at least two layers of high band gap material adjacent the template includes SiGeSn.

10. A method as claimed in claim 9 wherein the at least two layers of high band gap material further include epitaxially and sequentially grown layers of InGaAs and InGaP epitaxially grown on the layer including SiGeSn.

11. A method as claimed in claim 4 wherein the template further includes a layer of Ge epitaxially grown on the single crystal GeSn layer.

12. A method as claimed in claim 11 wherein a layer of the at least two layers of high band gap material adjacent the template includes SiGeSn.

13. A method as claimed in claim 12 wherein the at least two layers of high band gap material further include epitaxially and sequentially grown layers of InGaAs and InGaP epitaxially grown on the layer including SiGeSn.

14. A GeSn template on a silicon substrate comprising a crystalline silicon substrate and an epitaxially grown single crystal GeSn layer on the silicon substrate, the Sn being graded through the layer, and the single crystal GeSn layer having a thickness in a range of approximately 3 μm to approximately 5 μm.

15. A GeSn template on a silicon substrate as claimed in claim 14 wherein the grading starts with the Sn at or near zero with the Ge at zero, the percentage of Sn varies to a maximum mid-area, and reduces the percentage of Sn to zero adjacent an upper surface.

16. A solar cell on a silicon substrate comprising:
a crystalline silicon substrate;
an epitaxially grown template on the silicon substrate including an epitaxially grown single crystal GeSn layer on the silicon substrate, the Sn being graded through the layer, and the single crystal GeSn layer having a thickness in a range of approximately 3 μm to approximately 5 μm; and
at least two layers of high band gap material epitaxially and sequentially grown on the template forming at least three junctions.

17. A solar cell on a silicon substrate as claimed in claim 16 wherein each of the at least two layers of high band gap material includes material with a band gap in a range of 0.8 eV to 3 eV.

18. A solar cell on a silicon substrate as claimed in claim 13 wherein a layer of the at least two layers of high band gap material adjacent the template includes InGaAs.

19. A solar cell on a silicon substrate as claimed in claim 18 wherein another layer of the at least two layers of high band gap material includes a layer of InGaP epitaxially grown on the layer including InGaAs.

20. A solar cell on a silicon substrate as claimed in claim 17 wherein a layer of the at least two layers of high band gap material adjacent the template includes SiGeSn.

21. A solar cell on a silicon substrate as claimed in claim 20 wherein the at least two layers of high band gap material further include epitaxially and sequentially grown layers of InGaAs and InGaP epitaxially grown on the layer including SiGeSn.

22. A solar cell on a silicon substrate as claimed in claim 16 wherein the template further includes a layer of Ge epitaxially grown on the single crystal GeSn layer.

23. A solar cell on a silicon substrate as claimed in claim 22 wherein a layer of the at least two layers of high band gap material adjacent the template includes SiGeSn.

24. A solar cell on a silicon substrate as claimed in claim 23 wherein the at least two layers of high band gap material further include epitaxially and sequentially grown layers of InGaAs and InGaP epitaxially grown on the layer including SiGeSn.

25. A solar cell on a silicon substrate as claimed in claim 16 wherein the grading starts with the Sn at or near zero with the Ge at zero, the percentage of Sn varies to a maximum mid-area, and reduces the percentage of Sn to zero adjacent an upper surface.

26. A solar cell on a silicon substrate comprising:
a crystalline silicon substrate;
a template positioned on the silicon substrate including a single crystal GeSn layer on the silicon substrate, the Sn being graded through the layer, and the single crystal GeSn layer having a thickness in a range of approximately 3 μm to approximately 5 μm;
a first layer including single crystal SiGeSn grown on the template;
a second layer including single crystal InGaAs grown on the first layer;
a third layer including single crystal InGaP grown on the second layer; and
each of the first, second, and third layers being matched to the solar spectrum with optimized band gap energies.

27. A solar cell on a silicon substrate as claimed in claim 26 wherein the template and the first, second, and third layers are formed with band gap energies of 0.53/1.13/1.55/2.13 eV, respectively.
